(19) United States
(12) Patent Application Publication
(10) Pub. No.: US 2026/0276779 A1
(43) Pub. Date: Sep. 17, 2026

(54) A Remote Sensor RF Receiver System

(71) Applicant: Kevin J Rappoport, Evans, GA (US)

(72) Inventor: Kevin J Rappoport, Evans, GA (US)

(21) Appl. No.: 19/472,243

(22) PCT Filed: Apr. 5, 2024
(86) PCT No.: PCT/US2024/023411

§ 371 Date: Oct. 3, 2025

Related U.S. Application Data
(60) Provisional application No. 63/457,160, filed on Apr. 5, 2023.
(60) Provisional application No. 63/470,707, filed on Jun. 2, 2023.

(51) Int. Cl. G01S 7/03; H03M 1/12

(52) U.S. Cl. CPC G01S 7/03; H03M 1/12

(57) ABSTRACT

A remote sensor RF receiver system for efficiently collecting high-quality RF for transmission to a different location for processing and exploitation is described. The sensor's digital sub-sampling system uses Nyquist-folding with a plurality of sampling patterns to reduce the volume of data transmitted off the sensor while retaining the ability to detect weak signals, and produce high-quality signal characterizations and geolocations. The sensor adaptively alters the sampling patterns to reshuffle the folded spectra to 1) mitigate interference in the RF environment, 2) better distribute signals across the folded spectrum, and/or 3) increase SNR for signals of interest. The refolding commands can be generated on-board the sensor to adapt to the current RF environment, or can be accepted from an off-board processing center.

### RELATED REFERENCES

This application claims priority to and incorporates fully by reference U.S. provisional patent applications 63/457,160 filed on Apr. 5, 2023, and 63/470,707 filed on Jun. 2, 2023. Both applications have the same inventor as the present application.

### FIELD OF THE INVENTION

The invention addresses the efficient collection, storage, and transmission of Radio Frequency, or RF, data collected by a remote sensor and forwarded to a data center for processing and exploitation.

### BACKGROUND

Radio Frequency (RF) data is collected by remote sensors with limited cargo, power and processing capability, such as satellites, aircraft, balloons, drones, or other platforms, and is transmitted as digitized RF measurements to a data center or some other processing node with more capable storage and computing capabilities for processing and exploitation in various applications. The applications can include, but are not limited to, Synthetic Aperture Radar (SAR) imaging, Surveillance Radar, Bistatic Radar, Radar Warning Receivers and Radar Detectors, and Electronic Signals Surveillance.

For maximum utility, it is desirable to maximize the received bandwidth of the remote sensor and the fidelity of RF measurements made by the remote sensor while at the same time minimizing the cost of each remote sensor to collect, measure, store, and transmit the data to the off-board data center. Maximizing the fidelity of RF measurements increases the ability to detect and discern weak signals, and improves the quality of any geolocations that could be produced. Minimizing sensor cost and complexity enables the deployment of large numbers of cheap, expendable, and highly capable remote sensors.

The RF is captured as a sequence of electrical measurements which are eventually converted into a digital format, or digital samples, for processing, storage, and transmission. The fidelity of these digital samples to the actual analog signal collected determines the quality of information that can be extracted, and is greatly affected by the sequence of operations used to implement the conversion within the sensor. The range of RF frequencies that can be simultaneously collected, or received bandwidth, is determined by the rate at which the samples are collected.

The dual goals of maximizing received bandwidth and fidelity to the analog signals increases the volume of digital data collected at the sensor. As can be appreciated, however, higher data volumes can increase the on-board processing and storage requirements as well as the cost to move the data off the remote sensor to the main processing node. Higher data volumes can also increase the size, weight, complexity, and power requirements of the sensor, which in turn can dramatically increase the costs of the sensor and its deployment. Accordingly, it is desirable to use data reduction techniques on the sensor that maximizes the fidelity of data collected while reducing the volume of data transmitted off-board.

Prior Art FIG. 1 shows the current practice for a simple RF sampling receiver used in a typical remote sensor. RF is collected by an antenna as an analog signal with continuously varying voltage. The analog signal passes through a filter and a Low Noise Amplifier (LNA). The filtered and amplified signal is passed through a Bandpass Filter which suppresses all frequencies except those in the desired frequency range (the passband). The difference between the highest and lowest frequencies in the passband is the received bandwidth. The Passband is then digitized by an Analog to Digital Converter (ADC) which samples the analog signal at a constant rate and converts the sampled voltages into digital values. The important design principle is that the sampling rate of the ADC is matched to the bandwidth of the Bandpass Filter. The sampling rate must be at least two times the bandwidth to allow correct reconstruction of the signal from digital samples. When the sampling rate of the ADC is less than the required minimum value, so-call undersampling, subsampling, or Sub-Nyquist sampling, the signals in the passband can become irreversibly distorted such that they cannot be recovered from the digitized samples.

Prior Art FIG. 2 shows how a remote sensor's analog signal can be sampled and transformed by analog processes prior to being converted into digital format for the purpose of reducing the volume of digital data stored on or exported from the sensor. This process is described in U.S. Pat. No. 11,251,832, which is incorporated by reference herein. The data reduction process is accomplished by using a multiplicity of analog processing channels operating in parallel (elements 500, 1006, 1008, 1012 in the figure). First, the input analog signal 502 is subsampled at regular intervals below the Nyquist Rate by independent samplers 602, . . . 608 as controlled by clocks 510, . . . 516. The sampled signals are passed through multiple independent analog interpolator circuits 1006 which smooth and interpolate the voltage between sampled voltage levels. The interpolated analog signals are then amplified in parallel in 1008, and digitized in parallel in 1012 using independent Analog to Digital Converters (ADCs) 1092, . . . , 1098 synchronized by a second clock 1010.

The analog interpolation process performed in each analog processing channel can introduce distortions in the signal prior to measurement and digitization that reduces the fidelity and precision of the digital sample measurements from the ADC. Furthermore, the low-rate ADCs in module 1012 average the analog signals over a long sample time, which also results in reduced sample precision. The reduced fidelity of the voltage measurements to the original signal introduced by these two processing steps degrades the ability of the sensor to detect and discern weak signals, and reduces the quality of geolocations that could be produced.

The use of multiple analog channels with samplers operating at different constant Sub-Nyquist rates allows the system to sample the signal at lower rates than would normally be required to adequately capture the received RF bandwidth for certain classes of signals (but not all signals). Each sub-sampling channel creates a folded version of the full RF spectrum as shown in FIG. 3. The folding creates multiple issues. First, signals from different parts of the spectrum are folded on top of each other making detection and discernment of individual signals more difficult. Second, the actual RF of a signal is indeterminate since it is not known which fold the signal originally resided in. Third, a signal is folded on top of itself if the signal crosses a fold which can irretrievably destroy the signal content. The folds occur at constantly-spaced frequencies, so each fold has the same bandwidth. The bandwidth of the fold is determined by the sampling rate, and different folding patterns can be achieved by using different sampling rates.

Each constant-rate sampling channel in FIG. 2 creates a spectrum with a different folding pattern. The downstream processing and analysis functions 1014, 1040, 1042 use the multiple folded spectra to reconstruct the signals that would have been otherwise irretrievably distorted if only a single subsampled channel were used. U.S. Pat. No. 11,251,832 teaches the use of 3 or more subsampling channels operating at different rates to facilitate a suitably accurate reconstruction of the data contained in the original signal.

### BRIEF DESCRIPTION OF THE DRAWINGS

FIG. 1 is a simplified block diagram of a typical prior art receiver system as is utilized in remote sensors.

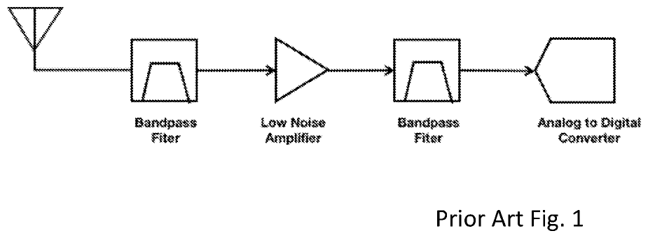

FIG. 2 is a block diagram of a prior art receiver system as taught in U.S. Pat. No. 11,251,832.

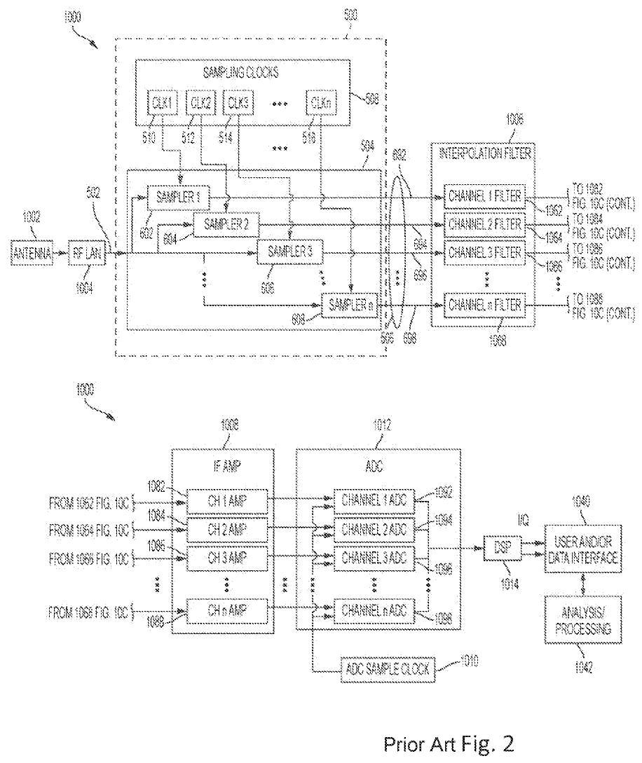

FIG. 3 is a graphical representation of the Nyquist folding technique as is utilized in receiver systems such as the prior art system shown in FIG. 2 and embodiments of the present invention.

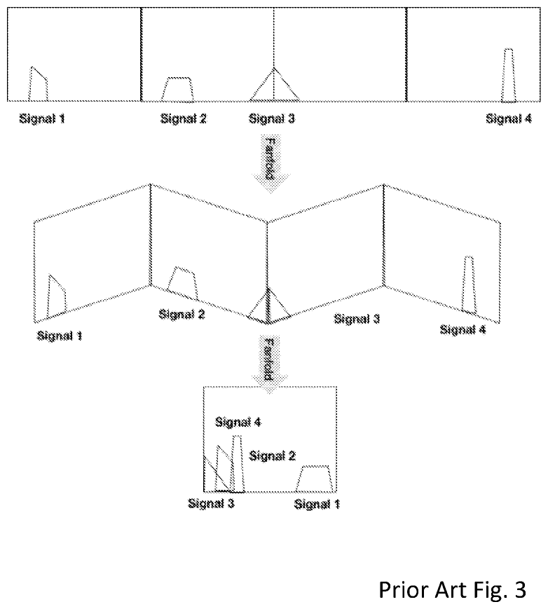

FIG. 4 is a block diagram illustrating a fully-autonomous remote sensor that continuously adapts to the RF environment without the need for external commanding according to a first embodiment of the present invention.

FIG. 5 is a flow chart illustrating the operations performed by the Adaptive Fold Estimator according to the first embodiment of the present invention.

FIG. 6 is a block diagram illustrating a fully-autonomous remote sensor that continuously adapts to the RF environment without the need for external commanding, which further includes a playback function according to a second embodiment of the present invention.

FIG. 7 is a block diagram illustrating an externally-commanded remote sensor in which the folding patterns are determined at the remote data center using the folded data streams and spectrum metadata passed through interface section according to a third embodiment of the present invention.

FIG. 8 is a block diagram illustrating an externally-commanded remote sensor with minimal on-board processing in which the folding patterns are determined at the remote data center using the folded data streams and spectrum metadata passed through interface section according to a fourth embodiment of the present invention.

FIG. 9 illustrates an application in which the remote sensor stores collected data for periodic export to a communications facility according to embodiments of the present invention.

FIG. 10 illustrates an application in which the remote sensor is either in continuous contact with a remote communications facility, or is broadcasting the collected data in real-time for receipt by any user with the appropriate communications equipment according to embodiments of the present invention.

### DETAILED DESCRIPTION

Embodiments of the present invention address the problem of efficiently collecting high-quality RF with a remote sensor for transmission to a different location for processing and exploitation. The invention uses Nyquist-folding with a plurality of sampling patterns, where each pattern uses a different sampling rate or modulating pattern, to reduce the volume of data transmitted off the sensor, while retaining the ability to detect weak signals, and to produce high-quality signal characterizations and geolocations. The sensor can adaptively alter the sampling patterns to reshuffle the folded spectra to 1) mitigate interference in the RF environment, 2) better distribute signals across the folded spectrum, or 3) increase SNR for certain signals of interest. The refolding commands can be generated on-board the sensor to adapt to the current RF environment, or can be accepted from an off-board processing center.

The embodiments provide several key improvements over prior art. Firstly, the invention avoids distortion in the RF signals by directly measuring the analog signal in the full received bandwidth using much shorter averaging times as afforded by the ADC operating at the Nyquist rate. Secondly, the invention adaptively changes the RF folding pattern in response to the current RF environment to reduce interference between different signals folded on top of each other or distortions caused by a signal of interest crossing a fold. Thirdly, the invention allows for the use of metadata describing the received spectrum to facilitate accurate reconstruction of the signal from as few as two independent samplers.

Whereas the use of three or more constant-rate analog samplers described in U.S. Pat. No. 11,251,832. The embodiments described herein provide improvements over this approach by enabling the use of as few as two folding patterns using different constant-rate and modulated patterns, where no two samplers use the same sampling rate or sampling pattern. This improvement is enabled by the use of carefully-designed folding patterns combined with specialized reconstruction techniques, or the addition of a spectral metadata stream that can be used to guide signal reconstruction from as few as 2 Sub-Nyquist Sampled data streams.

U.S. Pat. No. 11,251,832, and other related prior, maintain the sampled RF as an analog signal that is interpolated and filtered through analog circuitry prior to digitization by a low-rate Analog to Digital Converter (ADC), which introduces distortions in the signal prior to digitization. Additionally, digitizing the subsampled and interpolated analog signal with a low-rate ADC averages the analog values for each digital sample over a relatively long period of time resulting in lower-fidelity measurement and decreased time precision. In contrast, the disclosed embodiments utilize high-rate digitization with shorter-duration averaging periods operating directly on the unadulterated RF signal allowing the embodiments to achieve both higher fidelity to the original signal, and better time-precision in the digital samples. The improved fidelity and time precision improves receiver sensitivity, enables better signal characterization, and facilitates better geolocation accuracy.

The ability of the embodiments to adaptively change folding patterns allows the receiver to better separate signals of interest from nuisance interferors in the constantly-changing RF environment, or to track RF-agile signals as they wander through the RF environment. The ability to autonomously adapt folding patterns, as embodied in at least one embodiment, offers significant advantages for collection systems that must store data for periodic offloading, such as might occur with (i) a low-cost satellite that can only downlink data when it passes over a ground site, or (ii) a non-communicating surveillance drone that collects and stores data that is manually offloaded when the drone returns to base.

As can be appreciated, multiple embodiments are anticipated depending various factors including the complexity of the on-board processing required to adaptively refold the data as dictated by size, weight, and power constraints of the remote sensor and/or requirements dictated by the sensor's mission criteria. For example, a simple adaptive strategy for use on a very low-cost sensor would be to set default sampling rates as a function of sensor location and tuned RF, or to allow the external processing center adaptively command sampling rate changes based on data received from the sensor. A more capable sensor may have the ability to monitor the spectrum on-board, and adapt the sampling rates autonomously.

### Terminology

The terms and phrases as indicated in quotes (“ ”) in this section are intended to have the meaning ascribed to them in this Terminology section applied to them throughout this document including the claims unless clearly indicated otherwise in context. Further, as applicable, the stated definitions are to apply, regardless of the word or phrase's case, to the singular and plural variations of the defined word or phrase.

The term “or” as used in this specification and the appended claims is not meant to be exclusive, rather the term is inclusive meaning “either or both”.

References in the specification to “one embodiment”, “an embodiment”, “a preferred embodiment”, “an alternative embodiment” and similar phrases mean that a particular feature, structure, or characteristic described in connection with the embodiment is included in at least an embodiment of the invention. The appearances of the phrase “in one embodiment” in various places in the specification are not necessarily all meant to refer to the same embodiment.

The term “couple” or “coupled” as used in this specification and the appended claims refers to either an indirect or direct connection between the identified elements, components or objects. Often the manner of the coupling will be related specifically to the manner in which the two coupled elements interact.

Directional and/or relationary terms such as, but not limited to, left, right, nadir, apex, top, bottom, upper, lower, vertical, horizontal, back, front and lateral are relative to each other and are dependent on the specific orientation of an applicable element or article, and are used accordingly to aid in the description of the various embodiments and are not necessarily intended to be construed as limiting.

Unless otherwise indicated or dictated by context, the terms “approximately” and “about” mean +−20%. Unless otherwise indicated or dictated by context, the term “substantially” means +−10%. The term “generally” means for the most part.

An “Analog to Digital Converter”, or “ADC” is an electronic device that samples an analog signal as either a single voltage or as In-phase and Quadrature (I&Q) voltage pairs at regular intervals and converts the measured values into a stream of digital numbers.

An “Analog Signal” is a continuously varying voltage within an electrical circuit that can be operated on by analog components to perform amplification, filtering, interpolation, and voltage measurement.

A “Passband” is a continuous range of frequencies with defined upper and lower frequency values.

A “Bandpass Filter”, or “BPF” is an analog component that passes a continuous range of frequencies, or passband, while suppressing frequencies outside that range.

A “Bandwidth” is the difference between the upper and lower bounds for a continuous range of frequencies.

A “Received Bandwidth” is the range of RF frequencies simultaneously collected by the receiver and converted to a digital format for storage on-board and/or export off-board the receiver.

A “Digital Sample” is a single measurement of voltage, amplitude, or some other electrical parameter of an analog signal taken at an instant in time and converted into a digital value.

A “Digitized Signal” is a sequence of digital samples that represent a series voltage measurements made on an analog signal over time.

A “Folded Spectrum”, or “Nyquist-folded Spectrum”, is a frequency spectrum with aliasing produced by performing a Fourier Transform on signals sampled at less than the Nyquist rate.

A “Interferor” is a signal that is near a signal of interest in frequency and interferes with accurate detection or measurements of the signal of interest.

“Signal of Interest” is a signal in the RF environment that is of interest for detection and further processing.

A “Low Noise Amplifier”, or “LNA”, is an analog device to amplify an analog signal with low distortion.

A “Nyquist Rate” is the rate at which a signal must be sampled in order to prevent aliasing. The Nyquist rate is twice the signal frequency.

“Nyquist-Sampled Data” is a is digitized signal in which the digital samples have been measured at a constant rate, and the measurement rate is at, or above, the Nyquist rate. For the purposes of this application, the output of an ADC is “Nyquist-Sampled Data”

“Nyquist-Rate Spectrum” is a sequence of power measurements for a range of frequencies produced from “Nyquist-Sampled Data”

“Folded Spectrum” is a sequence of power measurements for a range of frequencies produced from “Sub-Nyquist-Sampled Data”

“Sub-Nyquist-Sampled Data” is a subset of the digital samples drawn from a “Nyquist-Sampled Data”.

A “Signal to Noise Ratio”, or “SNR”, describes the relative energy in a signal of interest to the noise background.

A “Subsampled signal” is analog or digital signal in which samples are taken at below the Nyquist rate.

A “Masking Pulse” is an electrical signal within the subsampling circuit that is time synchronized to the ADC, or a digital time stamp within a digital data stream that controls the selection of digital samples in the Nyquist-Sampled Data. When the pulse is “on” the ADC sample is selected for inclusion in the Sub-Nyquist Sampled data stream. When the pulse is “off” the ADC sample is discarded.

“Spectrum Metadata” comprise any data describing the spectrum of a signal at a particular point in time. It can include, but is not limited to, the FFT of Nyquist-sampled data stream, the FFT of one or more Sub-Nyquist Sampled data streams, frequency bounds, detected or thresholded FFT outputs, data generated by filtering lattices or networks, or other frequency-related measurements.

“Store-and-forward” is a data export strategy in which data is collected and stored on-board for periodic export in burst transmissions. The strategy is contrasted with a continuous communication technique in which the data is continuously broadcast to an unspecified user or continuously beamed to communications nodes of a data relay service.

### A First Embodiment of a Folding Receiver

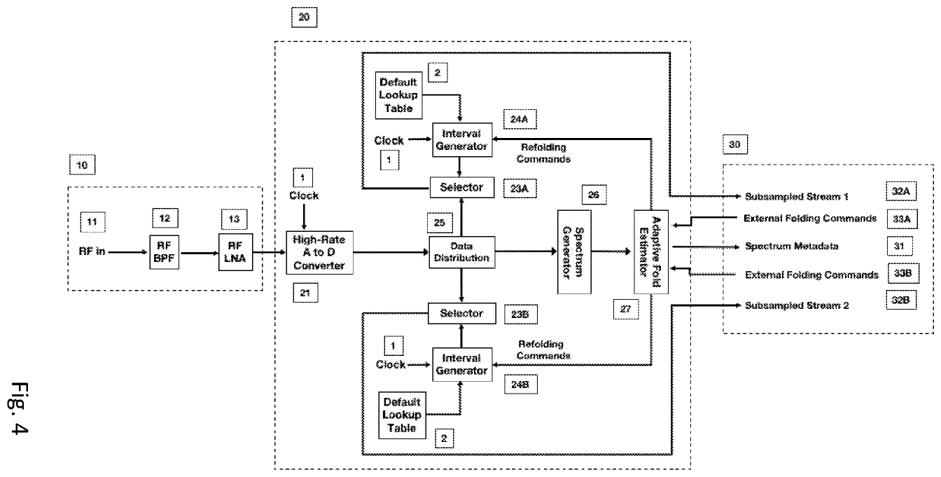

FIG. 4 shows an embodiment of an autonomously-adaptive folding receiver. The embodiment illustrates a folding receiver with two samplers operating with different sampling rates or sampling patterns and associated components 23A/B, 24A/B, 32A/B, and 33A/B. However, it is anticipated that the embodiment can be generalized to any number of folding samplers, with corresponding additional components for elements 23,24,32, and 33.

The RF energy is collected and input to the analog section 10 by interface 11. The received analog signals are passed through a Band Pass Filter (BPF) 12 where frequencies outside the desired range of frequencies (the bandpass) are suppressed. The bandpass-filtered signal is then passed through a Low Noise Amplifier (LNA) 13 where the desired frequency range is amplified for sampling. The analog signal from the LNA is passed to the digital processing segment 20 where it is processed by a high-rate Analog to Digital Converter (ADC) 21 that samples the voltage at regular intervals as controlled by a common constant-rate clock 1. The ADC 21 operates at or above the Nyquist rate of the BPF 12 such that the sampling rate of ADC 21 is at least two times the bandwidth of the BPF 12. The digitized stream of constant-interval samples from the ADC contains all the information required to represent any signal appearing in the analog signal output by the BPF 12 without distortion or loss of fidelity. The Nyquist-sampled data from the ADC is distributed through Data Distribution node 25 to a multiplicity of selectors 23A/B, and to the Spectrum Generation function 26.

The folding pattern is determined in a two-step process. First, data samples from the Data Distribution node 25 are processed by an FFT or other spectrum generation algorithm 26 to produce a digital representation of the relative power of each frequency in the received bandwidth. The digitized spectrum generated by Spectrum Generator 26 is passed to the Adaptive Fold Estimator 27 that determines the optimal folding patterns to use to minimize the data volume of the folded streams while maximizing one or more collection criteria provided in External Folding Commands 33A/B supplied by the remote data center.

The external folding commands 33A/B that control the fold optimization algorithm can include any of several optimization criteria, that could include, but is not limited to the following: 1) use one or more of the folding patterns in a passed list without attempting optimization; 2) optimize separation of signals using only folding patterns in the passed list; 3) maximize separation of any signals in a passed list of frequency ranges; 4) maximize separation of any signals not in the passed list of frequency ranges; 5) maximize separation of certain signal types; 6) minimize overlap of signals in the passed list of frequency ranges.

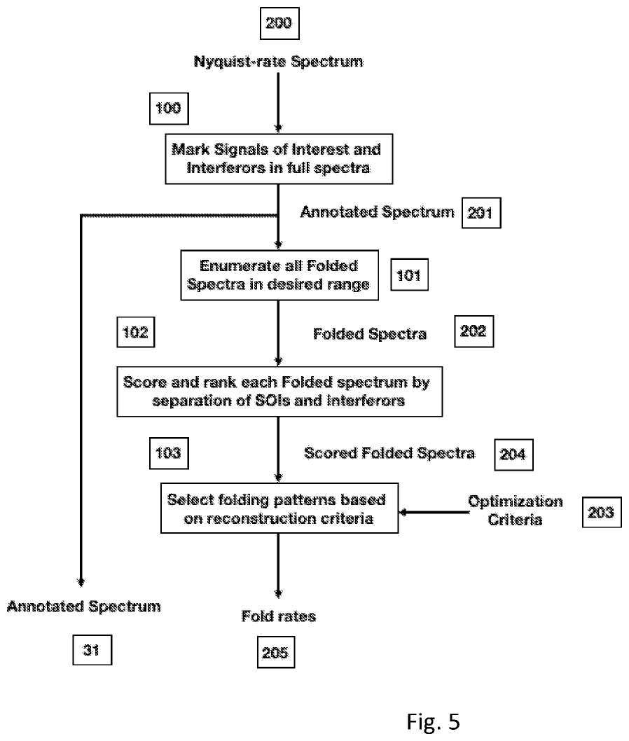

The optimization performed in the Adaptive Fold Estimator 27 is most easily understood as a sequence of operations performed on the Nyquist-rate spectrum 200 as shown in FIG. 5. The Nyquist-rate spectrum 200, created by the Spectrum Generator 26, is scanned in step 100 to identify likely signals of interest and nuisance interferors, and the signals are annotated on the spectrum 201. The annotated Nyquist-rate Spectrum 201 is passed to a fold-enumeration step 101 that folds the annotated spectrum by allowable folding factors to create a candidate set of folded spectra 202 annotated with the locations of signals of interest and interferors in the folded spectra. The annotated Nyquist-rate Spectrum 201 is optionally output from the function as spectral metadata through interface 31 to assist the external user in reconstructing the original spectrum from the folded spectra as might be required by some reconstruction algorithms. The collection of folded spectra 202 is scored and ranked in step 102 based on the distribution of Signals of Interest and/or interferors within each folded spectrum. The scored folded spectra 204 are passed to a final fold selection stage that chooses multiple folding patterns using the externally-supplied Optimization Criteria 203 from interfaces 33A/B to create the folding patterns 205 that are passed to the interval generators 24A/B.

The folding patterns, as provided through the external Folding Command interfaces 33A, 33B, or as calculated by the Adaptive Fold Estimator function 27, are used to create the duplicity of Sub-Nyquist Sampled streams 32A, 32B. FIG. 5 illustrates only two Sub-Nyquist Sampled streams for export, 32A and 32B, but alternate embodiments exist where more than two streams are exported. The refolding commands generated by the Adaptive Fold Estimator 27 instruct the interval generators 24A, 24B to implement one of several preprogrammed sampling patterns. In the absence of a folding command, such as upon initial start-up, the interval generators would utilize a default pattern provided by a look-up table 2 indexed by either 1) the tuned frequency band or 2) the tuned frequency band and current geographical location of the remote sensor, 3) previously accumulated metadata, or 4) any other metadata that may be useful in setting the initial sampling patterns.

The duplicity of interval generators 24A/B are disciplined by a common clock 1 and synchronized to the sample times of the ADC. The Interval Generators 24A and 24B provide a sequence of masking pulses that are time-synchronized to the ADC sample times to the Selectors 23A, and 23B. The selectors select samples from the ADC supplied through Data Distribution node 25 when the masking pulse as “on”, and omit samples when the masking pulse is “off”. The sequence of masking pulses produce the sub-Nyquist sampled streams provided to interfaces 32A/B for export. In this embodiment. The sampling patterns produced by the Interval Generators 24A and 24B can be constant-interval, where every nth sample is chosen for an arbitrary integer value of n or unevenly spaced such as would be produced by a Pseudo Random Number generator such as a Linear Recursive Sequence (LRS), or a linear ramp function, or a sinusoid, or any other pattern that provides data reduction while supporting exploitation of targeted signals at the remote data center.

### A Second Embodiment of a Folding Receiver

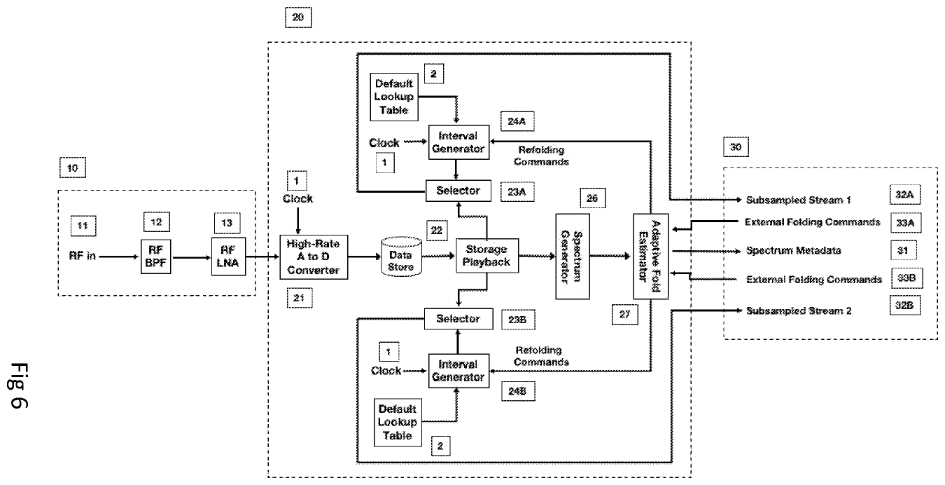

FIG. 6 shows a variation of the first embodiment in which a data store with data playback function 22 is used to maintain access to a short history of Nyquist-Sampled data output from the ADC 21. The playback function allows the sensor to re-fold and re-export data that was previously processed and exported off the sensor. The capability would allow the sensor to recover data that might otherwise have been lost by a poor initial choice of folding parameters that was corrected and fed back to the sensor through the external folding commands interface 33A/B.

The playback function allows the selectors 23A/B and spectrum generator 26 to access data from ADC 21 within a limited time horizon into the past for reprocessing and re-export. All other aspects of this embodiment operate in the same manner as the embodiment of FIG. 4. All similarly numbered elements and components and elements appear in this embodiment or any of the others are the same or substantially similar to the corresponding elements and components in the embodiment of FIG. 4 and the other embodiments described herein.

### A Third Embodiment of a Folding Receiver

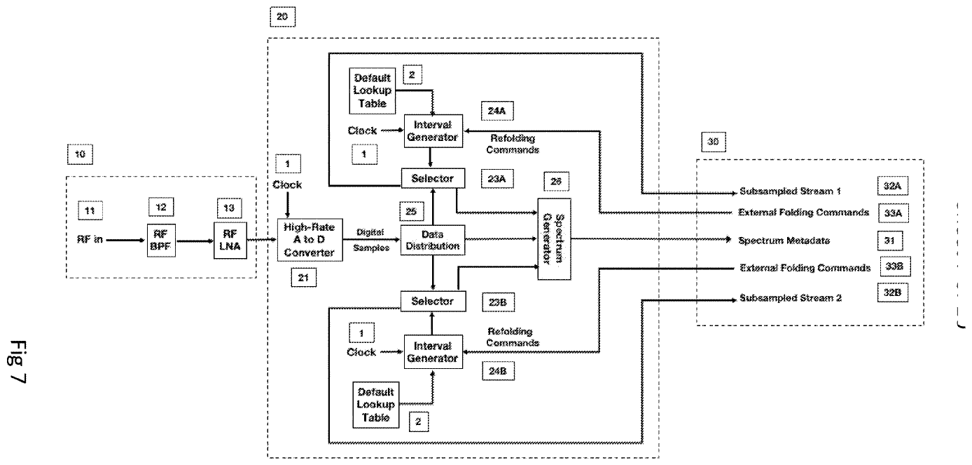

FIG. 7 illustrates a third embodiment in which the adaptive fold estimator 27 has been moved offboard the sensor. As in embodiment 1, the RF energy is input through interface RF-In 11, passes through a Band Pass Filter (BPF) 12 to suppress the frequencies outside the desired bandpass, and then through a Low Noise Amplifier (LNA) 13 where the selected frequency ranges are amplified for sampling. The analog signal from the LNA 13 is passed to a high-rate Analog to Digital Converter (ADC) 21 that samples the voltage at regular intervals as controlled by a common constant-rate clock 1.

The digitized stream of constant-interval samples from the ADC 21 is passed through a data distribution function 25. Data Distribution 25 delivers copies of the full sample stream to a multiplicity of sampler circuits as described in embodiment of FIG. 4, and a spectrum generation function 26. The spectrum generation function 26 creates a digital representation of the relative power of each frequency in the received bandwidth, as well as optionally producing spectra for the Sub-Nyquist Sampled streams to compute additional metadata describing the current folding strategy. The digitized spectra generated by Spectrum Generator 26 are exported from the receiver through the Spectrum Metadata interface 31 for use by an external processor in determining the optimal folding patterns.

Upon initial start-up, the interval generators would utilize a default pattern provided by a look-up table 2 as in embodiment 1. The external folding commands received through interfaces 33A/B can be continuously adapted by an off-board processor using the Sub-Nyquist Sampled streams 32A/B and the Spectrum Metadata 31 exported off the sensor. The external fold Optimization function serves the same purpose as the on-board Adaptive Fold Estimator 27 in the embodiment of FIG. 4, and operates in a similar manner.

The folding patterns, as provided through the external Folding Commands interfaces 33A, 33B, are used to create the duplicity of Sub-Nyquist Sampled streams 32A, 32B. FIG. 7 illustrates only two Sub-Nyquist Sampled streams for export, 32A and 32B, but alternate embodiments exist where more than two streams are exported. The external refolding commands passing through the External Folding interfaces 33A/B instruct the interval generators 24A/B to implement one of several preprogrammed sampling patterns. The duplicity of interval generators are disciplined by a common clock 1, and select samples from the data stream provided by the Data Distribution function 25.

As in the embodiment of FIG. 4, the unique set of sampling patterns produced by the Interval Generators 24A and 24B can be constant-rate, where every nth sample is chosen for an arbitrary integer value of n and each constant-rate sampler uses a different rate, or unevenly spaced such as would be produced by a Pseudo Random Number generator such as a Linear Recursive Sequence (LRS), or a linear ramp function, or a sinusoid, or any other pattern that provides data reduction while supporting exploitation of targeted signals at the remote data center.

### Fourth Embodiment of a Folding Receiver

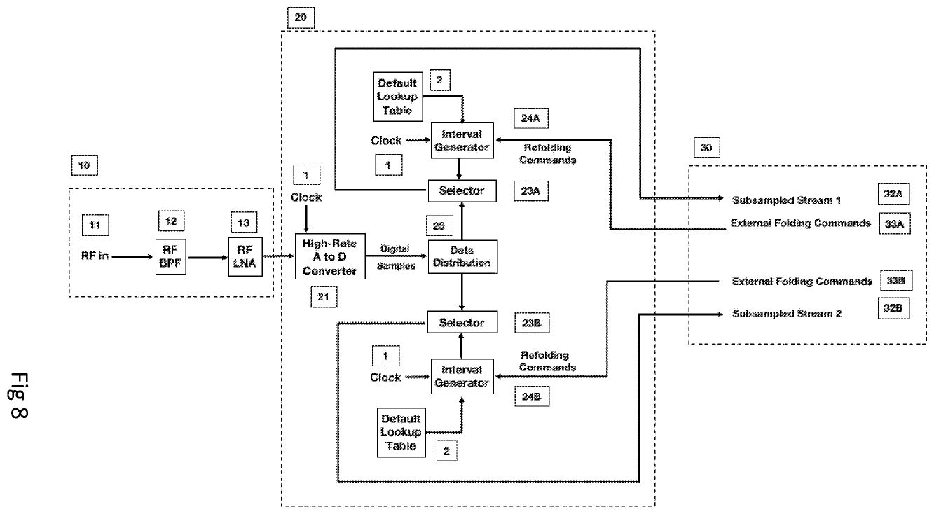

FIG. 8 shows a fourth embodiment of an adaptively-folding receiver designed for minimal cost in which all processing has been moved off-board. As in the embodiment of FIG. 7, the fold estimator 27 has been moved off-board so the sensor is reliant on external folding commands received through interface 33A/B to adapt the folding parameters to mitigate interference within the folded streams. The spectrum generation function 26 and associated spectrum data 31 interface has also been deleted so the off-board signal reconstruction functions must rely entirely on the folded data streams, or data from other sources, for signal reconstruction and fold adaptation.

### Methods of Using the Embodiments of the Folding Receiver

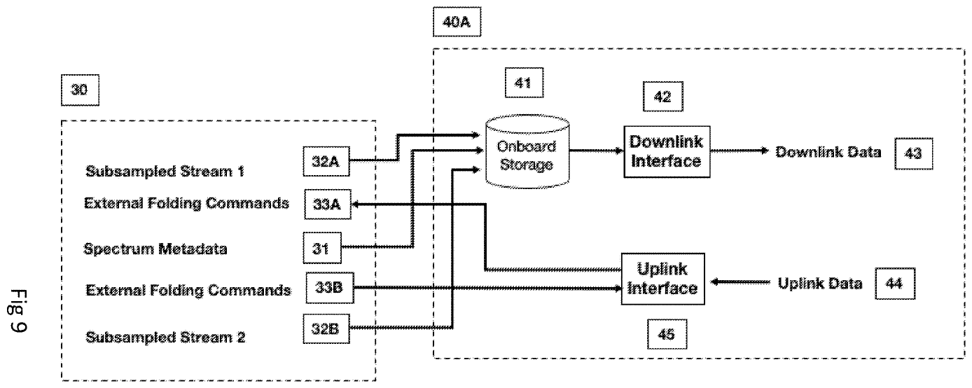

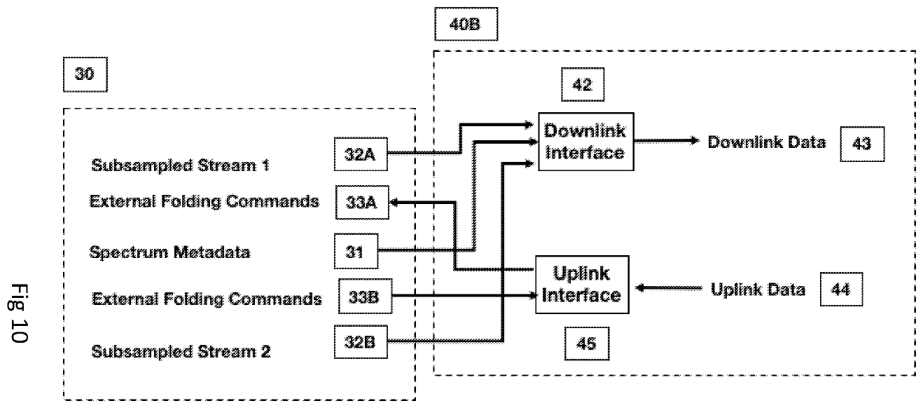

FIGS. 9 and 10 illustrate two anticipated methods to export receiver data to the remote processing facility. In both applications data flows through the interface section 30 to a communications interface 40A or 40B depending on the details of the application.

Communications interface 40A anticipates a store-and-forward communications concept in which the collection platform only has intermittent communications access. Communications interface 40B anticipates a direct-link communications concept in which the collection platform is in continuous contact with the remote processing facility.

FIG. 9 illustrates an application in which the remote sensor must store collected data for periodic export to a communications facility, such as might be required by a satellite that is able to export data and receive commanding only when it overflies a ground communications terminal. The figure illustrates an application using two simultaneous sample streams passing data through interface 32A/B and receiving commanding through interfaces 33A/B. Other applications may use more than two simultaneous sample streams which would result in additional sample stream interfaces 32 and additional folding command interfaces 33.

The data collected by the receiver, and supplied through interfaces 31, 32A, and 32B to the on-board storage system 41. When the platform is able to communicate, the receiver data is retrieved from the onboard storage 41 by the downlink interface 42. The data is then coded and formatted as downlink data 43 to be exported from the platform. Refolding commands are received from the communications system through interface 44, and are decoded and reformatted by the uplink interface 45.

FIG. 10 illustrates an application in which the remote sensor is either in continuous contact with a remote communications facility, or is broadcasting the collected data in real-time for receipt by any user with the appropriate communications equipment. The figure illustrates an application using two simultaneous sample streams passing data through interface 32A/B and receiving commanding through interfaces 33A/B. Other applications are anticipated using more than two simultaneous sample streams which would result in additional sample stream interfaces 32 and additional folding command interfaces 33.

The data collected by the receiver, and supplied through interfaces 31, 32A, and 32B to the downlink interface 42. Where the data is then coded and formatted as downlink data 43 to be exported from the platform. Refolding commands are received from the communications system through interface 44, and are decoded and reformatted by the uplink interface 45 to be passed to the external folding commands interfaces 33A/B.

I claim:

1. A digital sub-sampling system within an RF receiver, the digital sub-sampling system comprising:
an Analog to Digital Converter configured to convert an analog RF signal into Nyquist-Sampled Data;
a plurality of sampler circuits, each sampler circuit of the plurality of sampler circuits being configured to create a plurality of Sub-Nyquist Sampled Data streams using unique sampling rates; and
a constant-rate clock configured to time-discipline and synchronize the Analog to Digital Converter and the plurality of sampler circuits.

2. The digital sub-sampling system of claim 1, further comprising a data storage unit configured to store and playback (i) a time-contiguous span of Nyquist-Sampled Data output from the Analog to Digital Converter, and (ii) the Sub-Nyquist Sampled Data.

3. The digital sub-sampling system of claim 1, further comprising a communications interface configured to transmit the Sub-Nyquist Sampled Data.

4. The digital sub-sampling system of claim 2, further comprising a communications interface configured to transmit the Sub-Nyquist Sampled Data.

5. The digital sub-sampling system of claim 2, wherein the transceiver is further configured to receive instructions concerning the operational parameters for one or more of the plurality of sampler circuits.

6. The digital sub-sampling system of claim 1, wherein each of the plurality of sampler circuits include an interval generator operating from the constant rate clock to create masking pulses at a constant interval below the Nyquist rate of the Analog to Digital Converter.

7. The digital sub-sampling system of claim 1, wherein each of the plurality of sampler circuits include an interval generator operating from the constant rate clock to create masking pulses at nonconstant intervals as controlled by a pseudorandom number generator, or table of countdown intervals.

8. The digital sub-sampling system of claim 6, wherein each of the plurality of sampler circuits include a sample selector that chooses Sub-Nyquist Sampled Data based on masking pulses.

9. The digital sub-sampling system of claim 6, wherein each of the plurality of sampler circuits include a look-up table configured to set the default sampling pattern for each sampler.

10. The digital sub-sampling system of claim 9, wherein the lookup table is one of i) a 1-d table indexed by the currently tuned frequency band, ii) a 2-d table indexed by the currently tuned frequency band and current geographical location of the RF receiver, and iii) a table based on previous system performance.

11. The digital sub-sampling system of claim 6, further comprising for a communications interface coupled with the interval generator of each sampler circuit adapted to permit reprogramming of the sampling pattern.

12. The digital sub-sampling system of claim 6, further comprising a communications interface to receive refolding commands from an external source.

13. The digital sub-sampling system of claim 1, further comprising a Spectrum generator configured to measure and produce a digital representation of relative power of each frequency represented in the Nyquist-Sampled Data.

14. The digital sub-sampling system of claim 13, further comprising an adaptive fold estimator configured to optimize folding patterns based on the digital representation of relative power of each frequency represented in the Nyquist-Sampled Data.

15. A method of processing an analog RF signal using the digital subsampling system of claim 1, the method comprising:
receiving an analog RF signal;
using the Analog to Digital Converter converting the analog RF signal into Nyquist-Sampled Data; and
each sampler circuit sampling the Nyquist-Sampled Data according to different sampling patterns relative to the other sampler circuits wherein each sampler circuits creates unique creating Sub-Nyquist Sampled Data having Sub-Nyquist Sampled Data relative to the other sampler circuits.

16. The method of claim 15, further comprising: storing the Sub-Nyquist Sampled Data created by each sampler circuit in a data storage unit.

17. The method of claim 15, further comprising: transmitting the Sub-Nyquist Sampled Data to a remote location.
